(19) United States
(12) Patent Application Publication
(10) Pub. No.: US 2025/0014899 A1
(43) Pub. Date: Jan. 9, 2025

(54) METHOD FOR REMOVING UPPER PART OF SACRIFICIAL LAYER, AND SACRIFICIAL SOLUTION AND ACIDIC AQUEOUS SOLUTION USED THEREFOR

(71) Applicant: Merck Patent GmbH, Darmstadt (DE)

(72) Inventors: Takashi SEKITO, Kakegawa-shi (JP); Tatsuro NAGAHARA, Kakegawa-shi (JP)

(21) Appl. No.: 18/701,371

(22) PCT Filed: Dec. 20, 2021
(86) PCT No.: PCT/EP2021/086725

§ 371 Date: Apr. 15, 2024

(30) Foreign Application Priority Data
Dec. 23, 2020 (JP) 2020-213191

(51) Int. Cl. H01L 21/027; C08J 7/14; H01L 21/02; H01L 21/3105; H01L 21/311

(52) U.S. Cl. CPC H01L 21/0273; C08J 7/14; H01L 21/02118; H01L 21/31058; H01L 21/31133; H01L 21/31144; C08J 2325/18; C08J 2333/08

(57) ABSTRACT

[Problem] To provide a method for removing the upper part of a sacrificial layer. [Means for Solution] A method for removing the upper part of a sacrificial layer comprising the following steps: ·(1) applying a sacrificial solution comprising a polymer having an acid-dissociable protective group (A) and a solvent (B) above a substrate; ·(2) forming a sacrificial layer from the applied sacrificial solution; ·(3) subjecting an acidic aqueous solution to contact with the surface of the sacrificial layer; and ·(4) applying a remover to the sacrificial layer.

### BACKGROUND OF THE INVENTION

### Technical Field

The present invention relates to a method for removing the upper part of a sacrificial layer, and a sacrificial solution and an acidic aqueous solution used therefor. The present invention relates further to a method for manufacturing a processed substrate and a method for manufacturing a device.

### Background Art

In the manufacturing process of a device such as a semiconductor, not to process the portion other than intended one, a sacrificial film (or protective film) is formed for protection, processing is performed, and then the sacrificial film is removed (for example, Patent Document 1). With the progress of micronization in recent years, it is required to accurately form the film thickness of the sacrificial film.

Etch back is performed after the film formation in order to obtain the desired film thickness of the sacrificial film. Etch back can be performed by dry etching or wet etching. In order to improve the accuracy of the film thickness after etching back, it is conceivable to reduce the etching rate by making the sacrificial film highly resistant to etching or by devising the type or concentration of the chemical solution used for etching; however, this increases the processing time.

In Non-Patent Document 1, with respect to a material and process development for EUVL, various attempts are made in one viewpoint of suppressing the diffusion of acid in the non-exposed area. In the same document, the resist layer after exposure is peeled off, collected, molded, placed on another resin layer, and heated to obtain a film loss amount ΔL of the lower resin layer.

### PRIOR ART DOCUMENT

### Patent Document

[Patent document 1] WO 2003/015183

### Non-Patent Document

[Non-Patent Document 1] Development of EUVL material and process for 16 nm half pitch (Maruyama Lab., JSR TECHNICAL REVIEW No. 120/2013)

### SUMMARY OF THE INVENTION

### Problems to be Solved by the Invention

The present inventors considered that there are one or more problems still need improvements with respect to the method of removing the upper part of the sacrificial layer. Examples of these include the following: removing the upper part of the sacrificial layer to make the layer to the desired film thickness; controlling the thickness and depth of the upper part of the sacrificial film to be removed; reducing variation of the thickness and depth of the upper part of the sacrificial film to be removed and increasing the contrast; processing the part of the substrate at the specified height and depth; there is damage to the substrate when removing a part of the sacrificial film; improving filling properties of the sacrificial solution to the processed substrate; openings may shift each other when overlapping processed substrates; there are poor connections and variations in electrical characteristics in the device to be manufactured; the manufacturing yield is low; the device manufacturing process is complicated; and the device manufacturing time is long.

The present invention has been made based on the technical background as described above, and provides a method for removing the upper part of a sacrificial layer, a sacrificial solution and an acidic aqueous solution used for the method.

### Means for Solving the Problems

The method for removing the upper part of a sacrificial layer according to the present invention comprises the following steps:
(1) applying a sacrificial solution comprising a polymer having an acid-dissociable protective group (A) and a solvent (B) above a substrate;
(2) forming a sacrificial layer from the applied sacrificial solution;
(3) subjecting an acidic aqueous solution to contact with the surface of the sacrificial layer; and
(4) applying a remover to the sacrificial layer.

The method for manufacturing a processed substrate according to the present invention comprises the following steps:
preparing a substrate from which the upper part of the sacrificial layer is removed by the above method;
(5) performing surface treatment on the portion of the substrate from which the sacrificial layer is removed;
(6) removing the residual sacrificial layer; and
(7) subjecting the substrate to further processing.

The method for manufacturing a device according to the present invention comprises the above methods.

The sacrificial solution according to the present invention comprises a polymer having an acid-dissociable protective group (A) and a solvent (B), wherein the sacrificial solution forms a sacrificial layer, the sacrificial layer comes into contact with an acidic aqueous solution, and the upper part of the sacrificial layer is removed by a remover.

The acidic aqueous solution according to the present invention comprises an acid selected from the group consisting of the compounds represented by the following formulae (ZA), (ZB) and (ZC), and water, and is for being subjected to contact with a sacrificial layer:

R^{ZA}SO₃H (ZA)

wherein

R^{ZA} is C₁₋₁₀ fluorine-substituted alkyl, C₁₋₁₀ fluorine-substituted alkyl ether, C₆₋₂₀ fluorine-substituted aryl, C₁₋₁₀ fluorine-substituted acyl or C₆₋₂₀ fluorine-substituted alkoxyaryl;

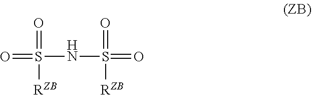

wherein

R^{ZB} is each independently C₁₋₁₀ fluorine-substituted alkyl, C₁₋₁₀ fluorine-substituted alkyl ether, C₆₋₂₀ fluorine-substituted aryl, C₁₋₁₀ fluorine-substituted acyl or C₆₋₂₀ fluorine-substituted alkoxyaryl, and the two R^{ZB} can be combined together to form a fluorine-substituted heterocyclic structure; and

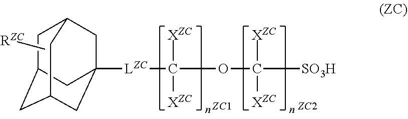

wherein
R^{ZC} is hydrogen, C₁₋₆ alkyl, C₁₋₆ alkoxy or hydroxy, and L^{ZC} is oxy or carbonyloxy;
X^{ZC} is each independently hydrogen or fluorine;
N^{ZC1} is 0 to 10; and
N^{ZC2} is 0 to 21.

### Effects of the Invention

According to the present invention, one or more of the following effects can be desired:

The upper part of the sacrificial layer can be removed to make the layer to the desired film thickness; the thickness and depth of the upper part of the sacrificial film to be removed can be controlled; variation of the thickness and depth of the upper part of the sacrificial film to be removed can be reduced and the contrast can be increased; the part of the substrate at the specified height and depth can be processed; damage to the substrate when removing a part of the sacrificial film can be reduced; filling properties of the sacrificial solution is high on the substrate; openings which shifted each other when overlapping the processed substrates can be connected; poor connections and variations in electrical characteristics in the device to be manufactured can be suppressed; the manufacturing yield can be improved; the device manufacturing process can be simplified; and the device manufacturing time can be shortened.

### BRIEF DESCRIPTION OF THE DRAWINGS

FIG. 1 A schematic illustration showing one embodiment of a method for removing the upper part of a sacrificial layer

FIG. 2 A schematic illustration showing one embodiment of a method for manufacturing a processed substrate

FIG. 3 A schematic illustration showing another embodiment of a method for manufacturing a processed substrate

FIG. 4 A schematic illustration showing another embodiment of a method for manufacturing a processed substrate

### DETAILED DESCRIPTION OF THE INVENTION

### Mode for Carrying Out the Invention

### [Definition]

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When a polymer has a plural types of repeating units, these repeating units copolymerize. This copolymerization may be any of alternating copolymerization, random copolymerization, block copolymerization, graft copolymerization, or a mixture thereof. When a polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the sacrificial solution according to the present invention as the solvent (B) or another component.

Hereinafter, embodiments of the present invention are described in detail.

### <Method for Removing the Upper Part of a Sacrificial Layer>

The method for removing the upper part of a sacrificial layer according to the present invention comprises the following steps:
(1) applying a sacrificial solution comprising a polymer having an acid-dissociable protective group (A) and a solvent (B) above a substrate;
(2) forming a sacrificial layer from the applied sacrificial solution;
(3) subjecting an acidic aqueous solution to contact with the surface of the sacrificial layer; and
(4) applying a remover to the sacrificial layer.

Hereinafter, each step is described with reference to the drawings. Although describing for clarity, the steps (1) and (2) are performed before the step (3). The numbers in parentheses indicating a step mean the order. The same applies hereinafter.

### Step (1)

In the step (1), the sacrificial solution is applied above the substrate.

Examples of the substrate include a silicon/silicon dioxide coated substrate, a silicon nitride substrate, a silicon wafer substrate, a glass substrate, and an ITO substrate. Since the present invention has a feature that the sacrificial layer is removed with high accuracy even when applied to a patterned substrate having irregularities, for example, a substrate having a trench shape with a high aspect ratio, the present invention is effective and preferable when a pattern substrate is used.

One preferable embodiment of the substrate is a Si substrate; one in which a plurality of types of Si-containing layers are laminated is more preferable. A structure in which insulating Si-containing layers and conductive Si-containing layers are alternately and continuously laminated is more preferable. Examples of the insulating Si-containing layer include a SiO₂ layer, and examples of the conductive Si-containing layer include a SiN layer. As such a structure, a structure in which a pair of an insulating Si-containing layer and a conductive Si-containing layer are alternately and continuously laminated 5 to 500 times is preferable; 10 to 300 times is more preferable; 50 to 300 times is further preferable. The bottom layer of the substrate is required to have function as a structural support, and a Si substrate can be mentioned as a preferable example of such a bottom layer.

The overall thickness of the substrate is preferably 1 to 20 μm; more preferably 4 to 15 μm; further preferably 5 to 10 μm.

Examples of the pattern substrate include a substrate having a contact hole. The conditions are severe at the part where the depth of the contact hole greatly exceeds the diameter. For example, when a contact hole is made by anisotropic etching, the diameter of the hole sometimes gradually decreases according to the depth. As an embodiment of the present invention, the ratio of the diameter to the depth of the contact hole at the part where conditions are most severe on a single pattern substrate is preferably 0.5:1 to 400:1; more preferably 0.5:1 to 300:1; further preferably 0.5:1 to 250:1; further more preferably 0.5:1 to 200:1.

As another embodiment, with respect to the aspect ratio of the pattern wall of the trench pattern substrate, at the part where the aspect ratio is the highest (the height of the wall greatly exceeds the width of the wall), the conditions such as removing the film become severe. As an embodiment of the present invention, the aspect ratio at the most severe part of the single pattern substrate is preferably 0.5:1 to 400:1; more preferably 0.5:1 to 300:1; further preferably; 0.5:1 to 250:1; further more preferably 0.5:1 to 200:1.

The pattern substrate can be formed by a known method. As the method for processing the pattern substrate, dry etching, wet etching, ion injection or metal plating method is preferable; dry etching or wet etching is more preferable; anisotropic dry etching or wet etching is further preferable; anisotropic dry etching is further more preferable. It is also possible to use a resist pattern as a mask. Examples of the gas atmosphere for anisotropic dry etching include N₂, NF₃, H₂, noble gas and fluorocarbon; preferably, Ar, Ne, NF₃, H₂, CF₄, CHF₃, CH₂F₂, CH₃F, C₄F₆, C₄F₈, and the like. Two or more of these gases can be mixed and used. The pattern substrate can be processed to form a conductive layer on the surface of contact holes and trenches (preferably excluding the bottoms thereof).

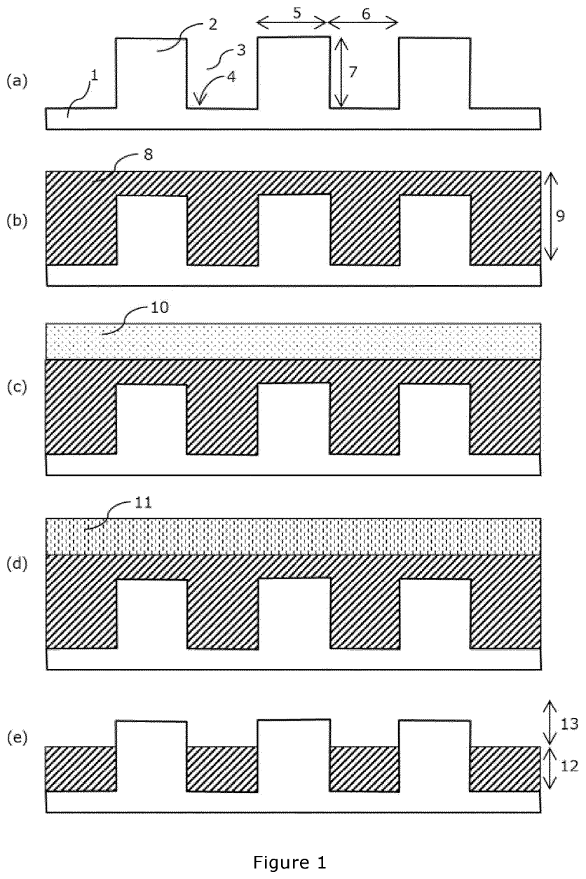

FIG. 1(a) is an example of a pattern substrate, in which the substrate 1 has a wall 2 having a wall width 5, and the part of a trench 3, which has a trench width 6 and a depth 7 from the trench bottom 4, is a blanked part.

The sacrificial solution described later is applied above a substrate by an appropriate method. Here, in the present invention, the “above a substrate” includes a case where a layer is formed immediately on a substrate and a case where a layer is formed above a substrate via another layer. For example, a planarization film or resist underlayer film can be formed immediately on a substrate, and the sacrificial solution can be applied immediately on it. The application method is not particularly limited, and examples thereof include a method using a spinner or a coater.

### [Sacrificial Solution]

A sacrificial solution according to the present invention comprises a polymer having an acid-dissociable protective group (A) (hereinafter, sometimes referred to as polymer (A)) and a solvent (B). This sacrificial solution is used for the method for removing the upper part of the sacrificial layer according to the present invention, that is, forming a sacrificial layer, thereafter, subjecting the sacrificial layer to contact with an acidic aqueous solution and removing the upper part of the sacrificial layer by a remover. Further, as another embodiment, the present invention provides a sacrificial solution comprising a polymer having an acid-dissociable protective group (A) and a solvent (B), wherein the sacrificial solution forms a sacrificial layer, the sacrificial layer comes into contact with an acidic aqueous solution, and the upper part of the sacrificial layer is removed by a remover.

### (A) Polymer Having an Acid-Dissociable Protective Group

The polymer (A) is one in which the protective group is dissociated by contact with an acidic aqueous solution described later and the solubility in the remover is increased. Generally, polymer used for the chemically amplified resist composition can be used. The polymer (A) can be synthesized or obtained by a known method.

The acid-dissociable protective group of the polymer (A) is a group represented by at least one formula selected from the group consisting of —C(R¹)(R²)(R³), —C(R¹)(R²)(OR⁴) and —C(R⁵)(R⁶)(OR⁴).

Preferably, the main chain and/or side chain of the polymer (A) has an acid-dissociable protective group; more preferably the main chain or side chain has an acid-dissociable protective group; further preferably the side chain has an acid-dissociable protective group.

Here,

R¹ to R⁴ are each independently alkyl, cycloalkyl, aryl, aralkyl or alkenyl, and R¹ and R² can be combined together to form a ring.

R⁵ and R⁶ are each independently hydrogen, alkyl, cycloalkyl, aryl, aralkyl or alkenyl.

The alkyl of R¹ to R⁶ is preferably C₁₋₈ alkyl, and examples thereof include methyl, ethyl, propyl, n-butyl, sec-butyl, hexyl, octyl and the like.

The cycloalkyl of R¹ to R⁶ can be a monocyclic type or a polycyclic type. As the monocyclic type, C₃₋₈ cycloalkyl is preferable, and examples thereof include cyclopropyl, cyclobutyl, cyclopentyl, cyclohexyl and cyclooctyl. As the polycyclic type, C₆₋₂₀ cycloalkyl is preferable, and examples thereof include adamantyl, norbornyl, isobornyl, camphanyl, dicyclopentyl, α-pinenyl, tricyclodecanyl, tetracyclododecyl, androstanyl and the like. At least one carbon atom in the cycloalkyl can be replaced with a heteroatom such as an oxygen atom.

The aryl of R¹ to R⁶ is preferably C₆₋₁₀ aryl, and examples thereof include phenyl, naphthyl, anthryl and the like.

The aralkyl of R¹ to R⁶ is preferably C₇₋₁₂ aralkyl, and examples thereof include benzyl, phenethyl, naphthylmethyl and the like.

The alkenyl of R¹ to R⁶ is preferably C₂₋₈ alkenyl, and examples thereof include vinyl, allyl, butenyl, cyclohexenyl and the like.

The ring formed by combining R¹ and R² is preferably cycloalkyl (monocyclic or polycyclic). As the cycloalkyl, monocyclic cycloalkyl such as cyclopentyl and cyclohexyl, and polycyclic cycloalkyl such as norbornyl, tetracyclodecanyl, tetracyclododecanyl and adamantyl are preferable. C₅₋₆ monocyclic cycloalkyl is more preferable, and C₅ monocyclic cycloalkyl is further preferable.

The polymer (A) comprises a repeating unit represented by the formulae (P-1), (P-2) and/or (Q). The polymer (A) more preferably comprises a repeating unit represented by the formula (P-1) and/or (P-2); further preferably comprises a repeating unit represented by the formula (P-1). Examples of the polymer (A) include polyhydroxystyrene (PHS)-based polymer and polymethylmethacryl (PMMA)-based polymer.

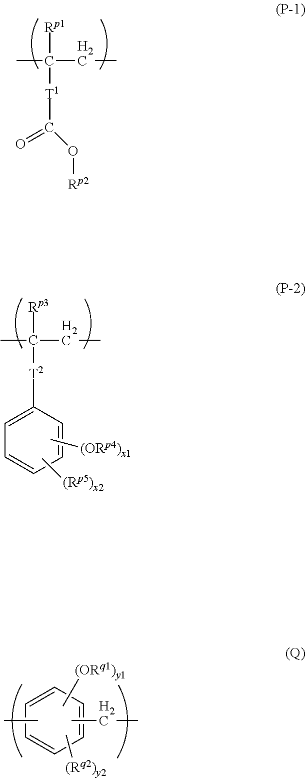

### Wherein

R^{p1} and R^{p3} are each independently hydrogen or C₁₋₄ alkyl; preferably hydrogen or methyl; more preferably hydrogen.

R^{p2}, R^{p4} and R^{q1} are each independently linear, branched or cyclic C₃₋₁₅ alkyl (where the alkyl can be substituted with fluorine and —CH₂— in the alkyl can be replaced with —O—). The C₃₋₁₅ alkyl of R^{p2}, R^{p4} and R^{q1} is preferably C₃₋₁₀; more preferably C₃₋₈; further preferably C₃₋₅; further more preferably C₄. Here, the above-mentioned “alkyl substituted with fluorine” means that H present in the alkyl is substituted with F. The above-mentioned substitution with fluorine means that all or part of H present in the alkyl is substituted with F, and all can be substituted. As one embodiment of the present invention, the C₃₋₁₅ alkyl of R^{p2}, R^{p4} and R^{q1} is not replaced with fluorine. Further, as one embodiment of the present invention, —CH₂— in the alkyl of R^{p2}, R^{p4} and R^{q1} is not replaced with —O—.

As one embodiment of the present invention, R^{p2}, R^{p4} and R^{q1} are each independently an acid-dissociable protective group represented by —C(R¹)(R²)(R³), —C(R¹)(R²)(OR⁴) or —C(R⁵)(R⁶)(OR⁴)—.

x1 and y1 are each independently 1 to 3; preferably an integer of 1 to 3; more preferably 1.

T¹ and T² are each independently a single bond or a C₁₋₁₂ linking group; preferably a single bond. Examples of the C₁₋₁₂ linking group of T¹ or T² each independently include a linking group consisting of alkylene, —COO-Rt-, —O-Rt-, or a combination of any two or more of these; preferably —COO-Rt-. Rt is alkylene or cycloalkylene; more preferably C₁₋₅ alkylene; further preferably —CH₂—, —(CH₂)₂— or —(CH₂)₃—.

R^{p5} is each independently C₁₋₅ alkyl (where —CH₂-in the alkyl can be replaced with —O—). R^{p5} is preferably C₁₋₄ alkyl; more preferably methyl or t-butyl; further preferably methyl. As one embodiment of the present invention, —CH₂— in the C₁₋₅ alkyl of R^{p5} is note replaced by —O—.

R^{q2} is each independently hydroxy or C₁₋₅ alkyl (where —CH₂— in the alkyl can be replaced with —O—); preferably hydroxy. The C₁₋₅ alkyl of R^{q2} is C₁₋₄ alkyl; more preferably methyl or t-butyl; further preferably methyl. As one embodiment of the present invention, —CH₂— in the C₁₋₅ alkyl of R^{q2} is not replaced by —O—.

x2 and y2 are each independently 0 to 2; preferably an integer of 0 to 2; more preferably 0.

As one preferable embodiment, the polymer (A) comprises repeating units represented by the group consisting of the formulae (P-1) to (P-4); and more preferably repeating units represented by the group consisting of the formulae (P-1) to (P-4) and the ratio of the repeating units other than the formulae (P-1) to (P-4) is 20 mol % or less; further preferably repeating units represented by the group consisting of the formulae (P-1) to (P-4).

As one preferable embodiment, the polymer (A) comprises (P-1) or (P-2) as a repeating unit. In one embodiment of the present invention, the polymer (A) comprises a repeating unit represented by any of the formulae (P-1) and/or (P-2) and a repeating unit represented by any of the formulae (P-3) and/or (P-4). Here, in the polymer (A), the ratio of the repeating units other than those represented by the formulae (P-1) to (P-4) is preferably 20 mol % or less, and more preferably, the polymer (A) consists of the repeating units represented by the group consisting of the formulae (P-1) to (P-4).

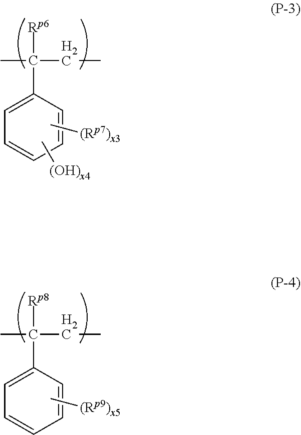

Wherein
R^{p6} and R^{p8} are each independently hydrogen or C₁₋₃ alkyl; preferably hydrogen or methyl; more preferably hydrogen.
R^{p7} and R^{p9} are each independently C₁₋₅ alkyl (where —CH₂— in the alkyl can be replaced with —O—). R^{p7} and R^{p9} are preferably C₁₋₄ alkyl; more preferably methyl or t-butyl; further preferably methyl. As one embodiment of the present invention, —CH₂— in the C₁₋₅ alkyl of R^{p7} and R^{p9} is not replaced with —O—.
x3 and x5 are each independently 0 to 2; preferably an integer of 0 to 2; more preferably 0.
x4 is 1 to 2; preferably an integer of 0 to 1; more preferably 1.

These repeating units are blended so that the increasing rate of solubility in the remover becomes appropriate upon contact with an acidic aqueous solution. The ratio of the repeating units (P-1) and (P-2) is preferably 5 to 50 mol %; more preferably 10 to 40 mol %, based on the total repeating units in the polymer.

In the polymer (A), the number of repeating units of the formulae (P-1), (P-2), (P-3) and (P-4) is taken as nₚ₁, nₚ₂, nₚ₃ and nₚ₄, respectively. nₚ₁/(nₚ₁+nₚ₂+nₚ₃+nₚ₄) is preferably 0 to 60%; more preferably 1 to 60%; further preferably 5 to 50%; further more preferably 10 to 30%.

nₚ₂/(nₚ₁+nₚ₂+nₚ₃+nₚ₄) is preferably 0 to 60%; more preferably 0 to 50%; further preferably 5 to 50%; further more preferably 5 to 30%. As one embodiment of the present invention, nₚ₂/(nₚ₁+nₚ₂+nₚ₃+nₚ₄)=0% is also preferable.

nₚ₃/(nₚ₁+nₚ₂+nₚ₃+nₚ₄) is preferably 0 to 90%; more preferably 5 to 80%; further preferably 30 to 80%; further more preferably 50 to 70%.

nₚ₄/(nₚ₁+nₚ₂+nₚ₃+nₚ₄) is preferably 0 to 60%; more preferably 1 to 50%; further preferably 5 to 40%; further more preferably 10 to 30%.

nₚ₁+nₚ₂>0%. At least one of nₚ₁ and nₚ₂ is greater than 0%; preferably nₚ₁ is greater than 0%.

It is preferable that nₚ₁, nₚ₂, nₚ₃ and nₚ₄ satisfy the following formulae:

$$0 \% \leq {n}_{p 1} / ( {n}_{p 1} + {n}_{p 2} + {n}_{p 3} + {n}_{p 4} ) \leq 60 \% , \\ 0 \% \leq {n}_{p 2} / ( {n}_{p 1} + {n}_{p 2} + {n}_{p 3} + {n}_{p 4} ) \leq 60 \% , \\ 0 \% \leq {n}_{p 3} / ( {n}_{p 1} + {n}_{p 2} + {n}_{p 3} + {n}_{p 4} ) \leq 90 \% , and \\ 0 \% \leq {n}_{p 4} / ( {n}_{p 1} + {n}_{p 2} + {n}_{p 3} + {n}_{p 4} ) \leq 60 \% ,$$

and that nₚ₁+nₚ₂>0% is satisfied The polymer (A) can also comprise repeating units other than (P-1), (P-2), (P-3) and (P-4). Here, it is preferable that the total number of all repeating units contained in the polymer (A) nₜₒₜₐₗ satisfies the following formula:

$$80 \% \leq ( {n}_{p 1} + {n}_{p 2} + {n}_{p 3} + {n}_{p 4} ) / {n}_{total} \leq 100 \% .$$

(nₚ₁+nₚ₂+nₚ₃+nₚ₄)/nₜₒₜₐₗ is more preferably 90 to 100%, further preferably 95 to 100%. It is also one preferable embodiment of the present invention that (nₚ₁+nₚ₂+nₚ₃+nₚ₄)/nₜₒₜₐₗ=100%, that is, no repeating units other than (P-1), (P-2), (P-3) and (P-4) are contained.

The content of the polymer (A) is preferably 5 to 50 mass %; more preferably 10 to 45 mass %; further preferably 20 to 40 mass %, further more preferably 30 to 35 mass %, based on the total mass of the sacrificial solution.

The mass average molecular weight (Mw) of the polymer (A) is preferably 2,000 to 200,000; more preferably 4,000 to 200,000; further preferably 8,000 to 20,000. Here, the mass average molecular weight means a mass average molecular weight in terms of polystyrene, which is measured by gel permeation chromatography.

### (B) Solvent

The solvent (B) is not particularly limited as long as it can dissolve each component to be blended, and can be freely selected from those generally used in the lithography method. The solvent (B) is preferably water, a hydrocarbon solvent, an ether solvent, an ester solvent, an alcohol solvent, a ketone solvent, or a combination of any of these.

Exemplified embodiments of the solvent (B) include water, n-pentane, i-pentane, n-hexane, i-hexane, n-heptane, i-heptane, 2,2,4-trimethylpentane, n-octane, i-octane, cyclohexane, methylcyclohexane, benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, trimethylbenzene, methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethyl nonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethyl carbinol, diacetone alcohol, cresol, ethylene glycol, propylene glycol, 1,3-butylene glycol, pentanediol-2,4,2-methylpentanediol-2,4, hexanediol-2,5, heptanediol-2,4,2-ethylhexanediol-1,3, diethylene glycol, dipropylene glycol, triethylene glycol, tripropylene glycol, glycerin, acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-i-butyl ketone, trimethylnonane, cyclohexanone, cyclopentanone, methylcyclohexanone, 2,4-pentanedione, acetonylacetone, diacetone alcohol, acetophenone, fenthion, ethyl ether, i-propyl ether, n-butyl ether (di-n-butyl ether, DBE), n-hexyl ether, 2-ethylhexyl ether, ethylene oxide, 1,2-propylene oxide, dioxolane, 4-methyl dioxolane, dioxane, dimethyl dioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, 2-methyltetrahydrofuran, diethyl carbonate, methyl acetate, ethyl acetate, γ-butyrolactone, γ-valerolactone, n-propyl acetate, i-propyl acetate, n-butyl acetate (normal butyl acetate, nBA), i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methyl cyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate (EL), n-butyl lactate, n-amyl lactate, diethyl malonate, dimethyl phthalate, diethyl phthalate, propylene glycol 1-monomethyl ether 2-acetate (PGMEA), propylene glycol monoethyl ether acetate, propylene glycol monopropyl ether acetate, N-methylformamide, N,N-dimethylformamide, N,N-diethylformamide, acetamide, N-methylacetamide, N,N-dimethylacetamide, N-methylpropionamide, N-methyl pyrrolidone, dimethyl sulfide, diethyl sulfide, thiophene, tetrahydrothiophene, dimethyl sulfoxide, sulfolane, and 1,3-propane sultone. These solvents can be used alone or in combination of two or more of these.

The solvent (B) is preferably PGME, PGMEA, EL, nBA, DBE or a mixture of any of these; more preferably PGMEA, PGME, EL, nBA, DBE or a mixture of any of these; further preferably a mixture of PGME and PGMEA. PGME, PGMEA, EL, nBA, DBE or a mixture of any of these, which are the above-mentioned preferable examples, are referred to as the solvent (B-1).

Although not to be bound by theory, it is also preferable that the sacrificial solution of the present invention contains a second solvent having a high boiling point in order to improve its filling properties. The second solvent is referred to as (B-2). (B-2) is preferably a high boiling point solvent. The boiling point is preferably measured at the normal boiling point. The normal boiling point of (B-2) is preferably 170° C. or higher; more preferably 180° C. or higher; further preferably 200° C. or higher; further more preferably 210° C. or higher. The normal boiling point of (B-2) is preferably 250° C. or lower; more preferably 240° C. or lower; further preferably 230° C. or lower.

Exemplified embodiments of (B-2) include γ-butyrolactone (204° C.), γ-valerolactone (207° C.), 1,3-butylene glycol diacetate (232° C.), benzyl alcohol (205° C.), 1,3-butylene glycol (208° C.), dipropylene glycol (230° C.), ethylene glycol monobutyl ether (171° C.), ethylene glycol monophenyl ether (244° C.), diethylene glycol monobutyl ether (231° C.), triethylene glycol monobutyl ether (271° C.), diethylene glycol monophenyl ether (283° C.), ethylene glycol monobenzyl ether (256° C.), diethylene glycol monobenzyl ether (302° C.), dipropylene glycol monomethyl ether (187° C.), and tripropylene glycol monomethyl ether (242° C.). These solvents (B-2) can be used alone or in combination of two or more of these.

As one embodiment of the present invention, the mass ratio {(B-1)+(B-2)}/(B) of the solvents (B), (B-1) and (B-2) contained in the sacrificial solution is preferably 90% or more; more preferably 95% or more; further preferably 98% or more; further more preferably 100%. As one embodiment of the present invention, the mass ratio (B-2)/(B-1) of the solvents (B-1) and (B-2) contained in the sacrificial solution is preferably 0 to 4/6; more preferably 0 to 1/9; further preferably 0 to 5/95; further more preferably 0.

It is also one embodiment that the solvent (B) substantially contains no water in relation to other layers and films. For example, the water content based on the total mass of the solvent (B) is preferably 0.1 mass % or less; more preferably 0.01 mass % or less; further preferably 0.001 mass % or less. It is also one preferable embodiment that the solvent (B) contains no water (0 mass %).

The content of the solvent (B) is adjusted depending on the coating method, the target film thickness and the like, and for example, it is preferably 50 to 95 mass %; more preferably 50 to 80 mass %; further preferably 60 to 70 mass %, based on the total mass of the sacrificial solution.

### (C) Acid Generator

The sacrificial solution according to the present invention can contain an acid generator (C). Examples of the acid generator (C) include a photoacid generator (PAG) that generates an acid by irradiation with light and a thermal acid generator (TAG) that generates an acid by heat. Since the acid for dissociating the acid-dissociable protective group of the polymer (A) can be obtained from the acidic aqueous solution of the step (3), it is not essential that the sacrificial solution of the present invention contains an acid generator to remove the upper part of the sacrificial layer.

The content of the acid generator (C) is preferably 0 to 5 mass %; more preferably 0 to 1 mass %; further preferably 0 mass %, based on the total mass of the sacrificial solution. As one embodiment of the present invention, it is preferable that no acid generator (C) is contained (0 mass %).

Further, as another embodiment of the present invention, making a PAG contained in the sacrificial solution, it is possible, after removing the upper part of the sacrificial layer, further, to expose and develop to make the sacrificial layer be patterned after removal. That is, it can also be used like a resist composition.

The PAG used in the sacrificial solution can be selected from the PAG used in conventionally known resist compositions. It is also possible to combine two or more types of PAG. The PAG is preferably an onium salt, more preferably an iodonium salt or a sulfonium salt.

When TAG is contained, it is important to control so that acid is not generated by heating in the process until the sacrificial layer is removed (before the step (4)). For that purpose, a TAG whose temperature required to generate an acid is higher than the heating temperature until the sacrificial layer is removed is preferable.

### (D) Additive

The sacrificial solution according to the present invention can contain an additive (D). The additive (D) is a surfactant, a basic compound, a contrast enhancer, a plasticizer or mixtures of any of these. As one embodiment of the present invention, the additive (D) is preferably a surfactant, a basic compound, a plasticizer or a mixture thereof; more preferably a surfactant or a basic compound; further preferably a surfactant.

The content of the additive (D) is preferably 0 to 10 mass %, more preferably 0.01 to 10 mass %; further preferably 0.01 to 5 mass %; further more preferably 0.01 to 3 mass %, based on the total mass of the sacrificial solution. Although describing for clarity, if the additive (D) is a mixture of a plurality of materials (for example, a surfactant and a plasticizer), the preferable content is calculated based on the sum of these. As one embodiment of the present invention, it is also preferable that no additive (D) is contained (0 mass %).

As an effect of containing a surfactant, improvement in coatability and/or improvement of filling properties in a pattern substrate can be expected. Examples of the surfactant that can be used in the present invention include (I) anionic surfactant, (II) cationic surfactant, or (III) nonionic surfactant, and more particularly, (I) alkyl sulfonate, alkyl benzene sulfonic acid and alkyl benzene sulfonate, (ii) lauryl pyridinium chloride and lauryl methyl ammonium chloride, and (iii) polyoxyethylene octyl ether, polyoxyethylene lauryl ether, polyoxyethylene acetylenic glycol ether, fluorine-containing surfactants (for example, Fluorad (3M), Megafac (DIC), Surflon (AGC) and organic siloxane surfactants (for example, KF-53, KP341 (Shinetsu Chemical Industry)).

These surfactants can be used alone or in combination of two or more of these. The content of the surfactant is preferably 0 to 2 mass %; more preferably 0.01 to 2 mass %; further preferably 0.1 to 1 mass %, based on the total mass of the sacrificial solution.

As an effect of containing a basic compound, when the sacrificial solution according to the present invention contains a photoacid generator and is exposed, it is possible to suppress the diffusion of the acid generated in the exposed area. Although not to be bound by theory, it is considered that containing the basic compound makes it possible to suppress the variation in the depth of removing the sacrificial film and increase the contrast.

Exemplified embodiments of the basic compound includes the following:
(i) ammonia,
(ii) C₁₋₁₆ primary aliphatic amines and derivatives thereof, such as methylamine, ethylamine, isopropylamine, tert-butylamine, cyclohexylamine, ethylenediamine, tetraethylenediamine,
(iii) C₂₋₃₂ secondary aliphatic amines and derivatives thereof, such as dimethylamine, diethylamine, methylethylamine, dicyclohexylamine, N,N-dimethyl-methylenediamine,
(iv) C₃₋₄₈ tertiary aliphatic amines and derivatives thereof, such as trimethylamine, triethylamine, dimethylethylamine, tricyclohexylamine, N,N,N′,N′-tetra-methylethylenediamine, N,N,N′,N″,N″-pentamethyl-diethylenetriamine, tris[2-(dimethylamino)ethyl]amine, tris[2-(2-methoxyethoxy)ethyl]amine,
(v) C₆₋₃₀ aromatic amines and derivatives thereof, such as aniline, benzylamine, naphthylamine, N-methylaniline, 2-methylaniline, 4-aminobenzoic acid, phenylalanine, and
(vi) C₅₋₃₀ heterocyclic amines and derivatives thereof, such as pyrrole, oxazole, thiazol, imidazole, 4-methylimidazole, pyridine, methylpyridine, butylpyridine.

The base dissociation constant pKb (H₂O) of the basic compound is preferably −12 to 5; more preferably 1 to 4.

The molecular weight of the basic compound is preferably 17 to 500; more preferably 60 to 400.

The content of the basic compound is preferably 0 to 1 mass %, more preferably 0.01 to 1 mass %, based on the total mass of the sacrificial solution. It is also one preferable embodiment that no basic compound is contained (0 mass %) in order to reduce the amount of acid to be diffused into the sacrificial layer.

Examples of the contrast enhancer include compounds having a low molecular weight, which are derived from an alkali-soluble phenolic compound or a hydroxycyclocyclic compound and contain an acid-labile group (hereinafter referred to as leaving group). Here, the leaving group reacts with the acid derived from the acid generator (C) to be eliminated from the compound, increases the solubility of the compound in the alkaline aqueous solution, and makes the contrast larger. Such a leaving group is, for example, —R^{r1}, —COOR^{r1} or —R^{r2}—COOR^{r1} (where R^{r1} is linear, branched or cyclic C₁₋₁₀ alkyl, which can contain an oxygen atom between carbon and carbon, and R^{r2} is C₁₋₁₀ alkylene), which can be replaced with hydrogen in a hydroxyl group bonded to the compound. Such a contrast enhancer preferably contains two or more leaving groups in a molecule. Further, the mass average molecular weight is 3,000 or less; preferably 100 to 2,000. Those preferable as the compounds before introducing a leaving group into hydroxy are as follows:

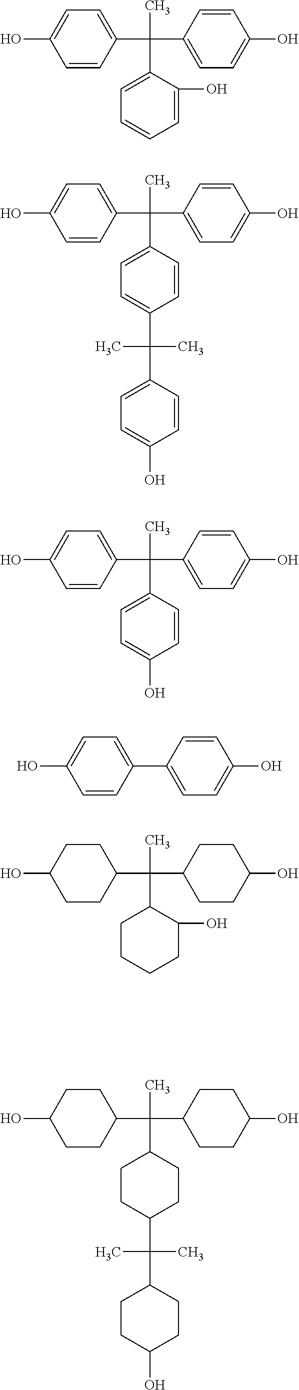

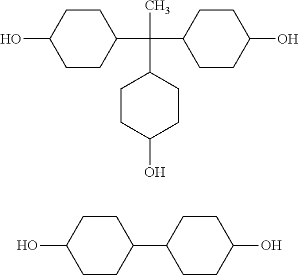 [SMILES: CC(C1CCC(O)CC1)(C1CCC(O)CC1)C1CCC(O)CC1 ; OC1CCC(C2CCC(O)CC2)CC1]

The contrast enhancer can be used alone or in combination of two or more. The content of the contrast enhancer is preferably 0 to 5 mass %, more preferably 0.1 to 5 mass %, based on the total mass of the sacrificial solution.

As an effect of containing a plasticizer, it can be expected to increase the elasticity of the sacrificial layer.

Examples of the plasticizer include alkali-soluble vinyl polymer and acid-dissociable group-containing vinyl polymer. More particularly, for example, polyvinyl chloride, polystyrene, polyhydroxystyrene, polyvinyl acetate, polyvinyl benzoate, polyvinyl ether, polyvinyl butyral, polyvinyl alcohol, polyether ester, polyvinyl pyrrolidone, polyacrylic acid, polymethacrylic acid, polyacrylic ester, polymaleimide, polyacrylamide, polyacrylonitrile, polyvinylphenol, novolak and copolymer of these are included, and polyvinyl ether, polyvinyl butyral and polyether ester are more preferable.

Exemplified embodiments of the plasticizer include the following:

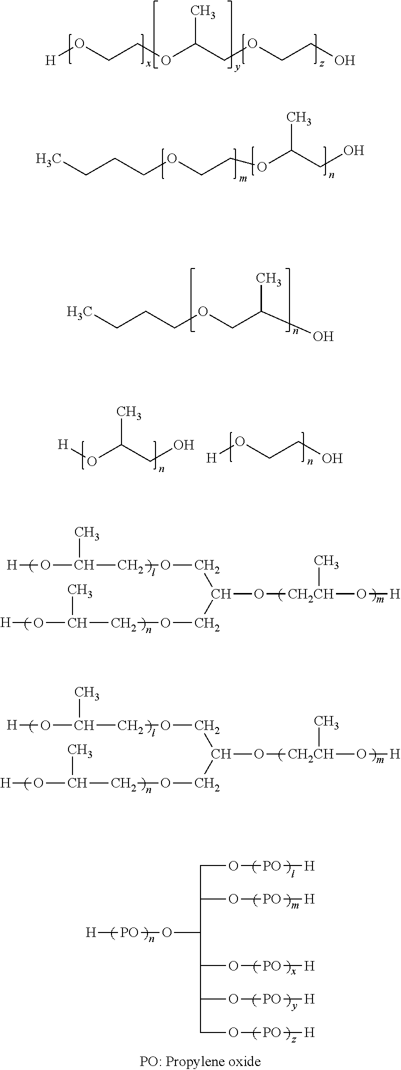

The mass average molecular weight of the plasticizer is preferably 1,000 to 50,000; more preferably 1,500 to 30,000; further preferably 2,000 to 21,000; further more preferably 2,000 to 15,000.

The content of the plasticizer is preferably 0 to 5 mass %; more preferably 0.1 to 5 mass %, based on the total mass of the sacrificial solution. It is also one preferable embodiment of the present invention that no plasticizer is contained (0 mass %).

The sacrificial solution according to the present invention can contain components other than the components (A) to (D), but the components other than the components (A) to (D) are preferably 5 mass % or less: more preferably 3 mass % or less: further preferably 0.5 mass % or less, based on the total mass of the sacrificial solution. It is also one preferable embodiment of the present invention that no components other than the components (A) to (D) are contained (0 mass %).

### Step (2)

In the step (2), a sacrificial layer is formed from the sacrificial solution.

On the substrate to which the sacrificial solution is applied, a sacrificial layer is formed preferably by heating. The heating in the step (2) is performed, for example, using a hot plate. The heating temperature is preferably 100 to 250° C.; more preferably 100 to 200° C.; further preferably 100 to 160° C. The temperature here is a heating atmosphere, for example, a heating surface temperature of the hot plate. The heating time is preferably 30 to 300 seconds; more preferably 30 to 120 seconds; further preferably 60 to 120 seconds. Heating is preferably performed in an air or nitrogen gas atmosphere; more preferably in an air atmosphere.

FIG. 1(b) shows a state in which the sacrificial layer 8 is formed on the substrate, and the height from the bottom is the film thickness (initial film thickness) 9. The film thickness of the sacrificial layer is selected depending on the intended purpose, but is preferably 1 to 30 μm; more preferably 2 to 20 μm; further preferably 3 to 15 μm.

It is preferable to further contain a step in which chemical mechanical polishing is conducted on the sacrificial layer, between the steps (2) and (3). Performing chemical mechanical polishing makes it possible to achieve planarization of the surface.

### Step (3)

In the step (3), an acidic aqueous solution described later is subjected to contact with the surface of the sacrificial layer.

FIG. 1(c) shows a state in which the acidic aqueous solution 10 is in contact with the sacrificial layer.

Examples of the method for contacting the acidic aqueous solution with the sacrificial layer include a paddle method, a dip method, and a spray (shower) method; preferably a paddle method or a dip method; more preferably a paddle method. The paddle method is a method in which a liquid is dropped onto a substrate from a nozzle, held for a certain period of time, and then the substrate is rotated by a spinner or the like to blow the liquid. The dip method is a method in which treatment is performed by immersing the whole substrate in a tank filled with a liquid for a certain period of time. The spray method is a method in which a treatment is performed by spraying a liquid from a plurality of nozzles onto a substrate. In the present invention, the contact time is preferably 10 to 600 seconds; more preferably 10 to 300 seconds; further preferably 20 to 180 seconds. Although not to be bound by theory, not too long contact time is preferable in order to improve the efficiency of device manufacturing, and it is considered that the contact time can be shortened by increasing the acid concentration or using an acid having a small pKa.

After contact with the acidic aqueous solution, preferably rinsing with a rinse liquid such as water is performed to replace the acidic aqueous solution. The acidic aqueous solution is preferably removed immediately after the above contact time, and when a rinse liquid is used, it is removed by replacement, and when a rinse liquid is not used, it is removed by spin dry or the like. The removal of the acidic aqueous solution is conducted after the lapse of the above contact time in preferably 0.5 to 180 seconds; more preferably 0.5 to 60 seconds; further preferably 1 to 60 seconds; further more preferably 5 to 30 seconds. Although not to be bound by theory, it is considered that if this interval is not controlled, acid diffusion progresses and the depth at which the sacrificial layer should be removed cannot be controlled. When a rinse liquid is used, the rinse liquid after replacing the acidic aqueous solution can be removed by a known method (for example, spin dry).

After that, it is preferable to heat the substrate. Although not to be bound by theory, by the heating in the step (3), the acid permeated from the surface of the sacrificial layer diffuses in the sacrificial layer. The heating in the step (3) varies depending on the film thickness of the film intended to remove, but the heating temperature is preferably 100 to 250° C.; more preferably 110 to 210° C.; further preferably 110 to 170° C. The heating time is preferably 30 to 600 seconds; more preferably 60 to 450 seconds; further preferably 180 to 450 seconds. The heating is conducted preferably in an air or nitrogen gas atmosphere; more preferably in an air atmosphere. Due to this acid, the protective group of the polymer having an acid-dissociable protective group is dissociated, the solubility of the polymer changes, and it becomes possible for the polymer to be removed by a remover. By adjusting the heating time and the heating temperature in the step (3), the diffusion region of the acid in the sacrificial layer, more preferably the depth thereof, can be controlled.

### [Acidic Aqueous Solution]

The acidic aqueous solution according to the present invention comprises an acid and water and is used for being contacted with the sacrificial layer. The acidic aqueous solution can contain components other than the acid and water. For example, the acidic aqueous solution can contain a surfactant. The components other than acid and water (in the case of a plurality of components, the sum of them) contained in the acidic aqueous solution are preferably 10 mass % or less; more preferably 5 mass % or less; further preferably 1 mass % or less; further more preferably 0 mass %, based on the total mass of the acidic aqueous solution.

As described above, the acid is not particularly limited as long as it dissociates the protective group of the polymer (A). Preferably, it is selected from the group consisting of the compounds represented by the following formulae (ZA), (ZB) and (ZC). The acid can be a mixture of any of these.

The compound represented by the formula (ZA) is as follows:

R^{ZA}SO₃H (ZA)

wherein

R^{ZA} is C₁₋₁₀ fluorine-substituted alkyl, C₁₋₁₀ fluorine-substituted alkyl ether, C₆₋₂₀ fluorine-substituted aryl, C₁₋₁₀ fluorine-substituted acyl or C₆₋₂₀ fluorine-substituted alkoxyaryl group. The substitution with fluorine means that all or part of hydrogen present in the alkyl moiety of R^{ZA} is substituted with fluorine. R^{ZA}is preferably C₁₋₁₀ fluorine-substituted alkyl; more preferably C₂₋₆ fluorine-substituted alkyl; further preferably C₂₋₄ fluorine-substituted alkyl. Further more preferably, it is perfluoroalkyl in which hydrogen are all substituted with fluorine.

Exemplified embodiments of the compound represented by the formula (ZA) include CF₃SO₃H, C₄F₉SO₃H or C₃F₇SO₃H; more preferably CF₃SO₃H.

The compound represented by the formula (ZB) is as follows:

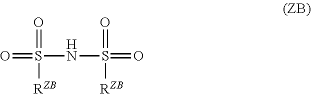

wherein

R^{ZB} is each independently C₁₋₁₀ fluorine-substituted alkyl, C₁₋₁₀ fluorine-substituted alkyl ether, C₆₋₂₀ fluorine-substituted aryl, C₁₋₁₀ fluorine-substituted acyl or C₆₋₂₀ fluorine-substituted alkoxyaryl, and the two R^{ZB} can be combined each other to form a fluorine-substituted heterocyclic structure. R^{ZB} is preferably C₁₋₁₀ fluorine-substituted alkyl; more preferably C₂₋₆ fluorine-substituted alkyl. Further, more preferably, it is perfluoroalkyl in which hydrogen are all substituted with fluorine.

When the two R^{ZB} are combined each other to form a fluorine-substituted heterocyclic structure, the heterocycle can be monocyclic or polycyclic. The heterocyclic structure can be a saturated ring or an unsaturated ring; more preferably a saturated ring. The number of members of the heterocycle is preferably 5 to 20; a monocyclic structure having 5 to 8 members is preferable. At this time, R^{ZB} is generally composed of a fluorine-substituted hydrocarbon chain, but is preferably perfluoroalkylene. R^{ZB} can further contain a heteroatom.

Exemplified embodiments of the compound represented by the formula (ZB) include the following:

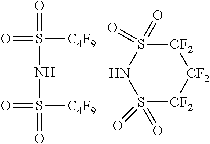

The compound represented by the formula (ZC) is as follows:

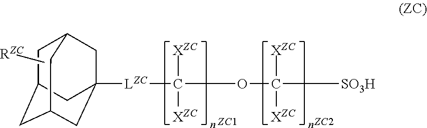

wherein
R^{ZC} is hydrogen, C₁₋₆ alkyl, C₁₋₆ alkoxy or hydroxy,
L^{ZC} is oxy or carbonyloxy,
X^{ZC} is each independently hydrogen or fluorine,
N^{ZC1} is 0 to 10, and
N^{ZC2} is 0 to 21.

Exemplified embodiments of the compound represented by the formula (ZC) include the following:

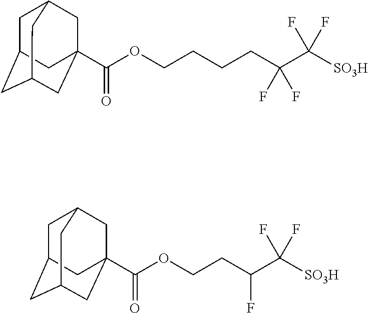 [SMILES: O=C(OCCCCC(F)(F)C(F)(F)S(=O)(=O)O)C12CC3CC(CC(C3)C1)C2 ; O=C(OCCC(F)C(F)(F)S(=O)(=O)O)C12CC3CC(CC(C3)C1)C2]

The acid dissociation constant pKa (H₂O) of the above-mentioned acid is preferably −20 to 2.5; more preferably −16 to 2.0; further preferably −16 to 1.5; further more preferably −16 to 1.2.

The acid content is preferably 0.0001 to 20 mass %; more preferably 0.001 to 20 mass %; further preferably 0.01 to 10 mass %; further more preferably 1 to 10 mass %, based on the total mass of the acidic aqueous solution.

### Step (4)

In the step (4), the remover described later is applied to the sacrificial layer.

FIG. 1(d) shows a state in which the remover 11 is applied to the sacrificial layer.

Examples of the method for applying the remover include a paddle method, a dip method and a spray method. The temperature of the remover is preferably 5 to 50° C.; more preferably 25 to 40° C., and the time for applying the remover is preferably 30 to 180 seconds; more preferably 60 to 120 seconds. After applying the remover, the remover is removed. By means of this treatment, a part of the sacrificial layer is removed. Typically, with a substantially uniform amount of film loss, the sacrificial layer is removed from the surface of the sacrificial layer of before the remover is applied.

Preferably, the removal of the remover is performed by rinsing with a rinse liquid such as water and replacing the remover. Rinsing by flowing a rinse liquid such as water on the surface of the substrate is also one preferable embodiment of the present invention. The removal of the remover is performed preferably in 0.5 to 180 seconds; more preferably in 0.5 to 60 seconds; further preferably in 1 to 60 seconds; further more preferably in 5 to 30 seconds, after the elapse of the remover application time.

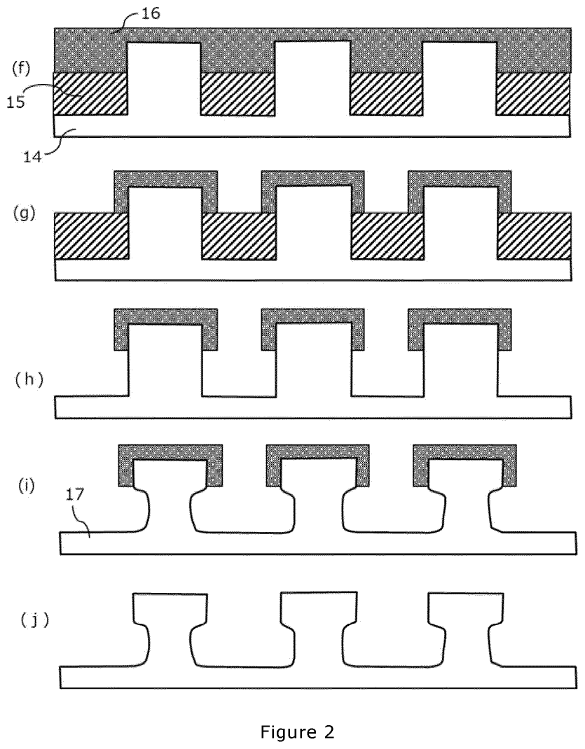

FIG. 2(e) shows a state in which the upper part of the sacrificial layer is removed, where in the sacrificial layer, the amount of film loss 13 is removed to become a film thickness of after removal 12.

According to the present invention, the amount of the film loss of the sacrificial layer can be controlled with high accuracy, and the sacrificial layer can be thinned for a desired depth.

### [Remover]

The remover has high solubility in the polymer in which a protective group is dissociated, and low solubility in the polymer in which a protective group is not dissociated. Preferably, it is an alkaline aqueous solution. Examples of the alkaline aqueous solution include aqueous solutions containing inorganic alkalis such as sodium hydroxide, potassium hydroxide, sodium carbonate and sodium silicate, organic amines such as ammonia, ethylamine, propylamine, diethylamine, diethylaminoethanol and triethylamine, and quaternary amines such as tetramethylammonium hydroxide (TMAH); more preferably a TMAH aqueous solution; further preferably a 2.38 mass % TMAH aqueous solution.

To the remover, it is also possible to further add the above-mentioned surfactant.

The present invention provides a method for manufacturing a processed substrate, which forms a substrate from which the upper part of the sacrificial layer is removed by the above-mentioned method and further comprises the following steps:
(5) performing surface treatment on the portion of the substrate from which the sacrificial layer is removed;
(6) removing the residual sacrificial layer; and
(7) subjecting the substrate to further processing.

### Step (5)

In the step (5), surface treatment of the substrate from which the sacrificial layer is removed is performed. The surface-treated portion becomes a mask in a later process. The surface treatment method is not particularly limited, and examples thereof include HMDS treatment and the like.

In FIG. 2(f), the sacrificial layer from which the upper part is removed 15 is formed on the substrate 14, and the surface treatment 16 is further filled. FIG. 2(g) shows a state in which the surface treatment 16 is further treated, and the sacrificial layer is exposed. The surface-treated portion acts as a protective film for the unprocessed portion.

### Step (6)

In step (6), all or part of the residual sacrificial layer is removed. As the method for removing all the sacrificial layer, methods generally used for peeling a resist can be used, and examples thereof include application of an organic solvent.

FIG. 2(h) shows a state in which the sacrificial layer is removed.

### Step (7)

In the step (7), the substrate is subjecting to further processing. Here, the surface-treated portion of the step (5) is masked, and only the substrate at the portion where the sacrificial layer removed in the step (6) is present is processed. The processing method is preferably dry etching or wet etching; more preferably wet etching. Although not to be bound by theory, it is considered possible to widen, at near the bottom, contact holes and trenches whose diameter gradually became narrower according to the depth, and to make the holes and trenches closer to a rectangular shape as a whole.

As the wet etching solution, general ones can be used, and examples thereof include hydrochloric acid, sulfuric acid, nitric acid, hydrofluoric acid, phosphoric acid, acetic acid, ammonia, potassium hydroxide, sodium hydroxide, tetramethylammonium hydride, hydrogen peroxide solution or a mixture of any of these.

FIG. 2(i) shows a state of the substrate 17 from which the sacrificial layer is removed and which is processed.

In the step (6), there is an embodiment in which the processing in the step (7) is performed in a state that a part of the residual sacrificial layer is removed. Thereby, it is possible to process not the bottom but the periphery of the center in the depth direction. There is an embodiment in which the substrate on which the holes and trenches are formed and the substrate on which the holes and trenches are similarly formed are overlapped to make the substrate thicker, but at this time, displacement of the holes and trenches sometimes causes. Although not to be bound by theory, it is possible to secure an electrical joint by increasing the width of the hole or trench in the joint portion by the above treatment. Thereby, it is possible to deal with poor filling of CIS wiring and the like, and to suppress poor connection and variation in electrical characteristics.

When removing a part of the residual sacrificial layer in the step (6), the methods described in the steps (2) and (3) can be repeated in the step (6). This makes it possible to remove the sacrificial layer to the desired depth. The repetition is preferably 1 to 3 times; more preferably 1 to 2 times; further preferably 1 time.

If necessary, the protective film can be removed to obtain a processed substrate.

According to the present invention, it is possible to easily manufacture a substrate in which only a certain portion of the substrate is processed.

Further, it is also possible to repeat the above steps two or more times to manufacture a substrate having a complicated structure.

The present invention provides a method for manufacturing a processed substrate which forms a substrate from which the upper part of the sacrificial layer is removed by the above-mentioned method and further comprises the following steps:
(5)′ processing the substrate by isotropic etching; and
(6)′ removing all or part of the residual sacrificial layer.

Here,

the steps (5)′ and (6)′ are carried out only once in this order or repeated alternately. The step (5)′ is carried out after the above steps (1) to (4). Although describing for clarity, the step subsequent to the step (5) and the step subsequent to the step (5)′ are different embodiments, and the step (5)′ does not follow the step (5).

Further, the present invention provides a method for manufacturing a processed substrate further comprises the following step after the steps (5)′ and (6)′:
(7)′ filling the portion where the sacrificial layer is removed with a conductive member.

### Step (5)′

In the step (5)′, the substrate is processed by isotropic etching. The substrate at the portion where the sacrificial layer is removed by the step (5)′ can be selectively processed. The isotropic etching is preferably wet etching.

Examples of the wet etching solution selected for processing the conductive Si-containing layer constituting the substrate include an aqueous phosphoric acid solution.

Examples of the wet etching solution selected for processing the insulating Si-containing layer constituting the substrate include an aqueous hydrofluoric acid solution.

When the substrate has a structure in which insulating Si-containing layers and conductive Si-containing layers are alternately and continuously laminated, it is possible to much etch any one of the layers using the above-mentioned selective wet etching solution. By changing the wet etching solution, the desired processing can be performed.

### Step (6)′

In the step (6)′, all or part of the residual sacrificial layer is removed. When removing a part of the residual sacrificial layer in the step (6)′, the methods described in the steps (2) and (3) can be repeated in the step (6)′.

By repeating the above steps (5)′ and (6)′, it is possible to process the substrate more at the shallow part and process the substrate less at the deep part, in the depth direction. This makes it possible to form holes and trenches that gradually become narrower in the depth direction. It is also one embodiment of the present invention to process with a wet etching solution that selectively processes the insulating Si-containing layer that finally constitutes the substrate.

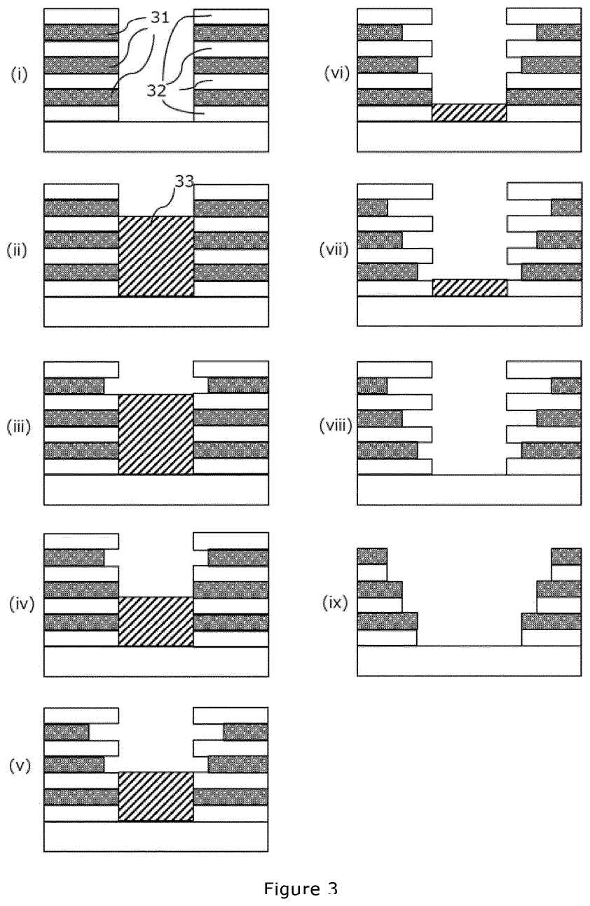

FIG. 3 is a schematic illustration showing one example of a manufacturing method in which the step (5)′ and the step (6)′ are repeated three times to form a stepped structure. FIG. 3(i) shows a state in which a substrate having a structure, in which conductive Si-containing layers 31 and insulating Si-containing layers 32 are alternately laminated, is made a structure having concavities using a photoresist or the like. FIG. 3(ii) shows a state in which a sacrificial layer 33 from which the upper part is removed by the method according to the present invention is formed in the concavities. FIG. 3(iii) shows states in which a part of the conductive Si-containing layer is processed by isotropic etching using the sacrificial layer as a mask. FIG. 3(iv) shows a state in which a part of the sacrificial layer is further removed. FIGS. 3(v) to (viii) show states in which the steps of isotropic etching and removal of the sacrificial layer are repeated. FIG. 3(ix) shows a state in which the insulating Si-containing layer is selectively subjected to wet etching from the state of (viii) to form a stepped structure.

### Step (7)

In the step (7)′, the conductive member is filled in the portion where the sacrificial layer is removed. Filling can be performed by a known method, for example, a conductive member melted by heating is poured. In the step (6)′ before the step (7)′, it is preferable that all of the residual sacrificial layer is removed. The conductive member is preferably a metal or a metal oxide; more preferably a metal. The metal referred to here can be an alloy or a pure metal. The alloy is preferably a metal composed of a plurality of metal elements. Since the shallow part in the depth direction of the substrate can be processed to make widened by the step (5)′, it is possible to form a conductive member having a wide structure in the lateral direction at the upper part and an elongated structure at the lower part.

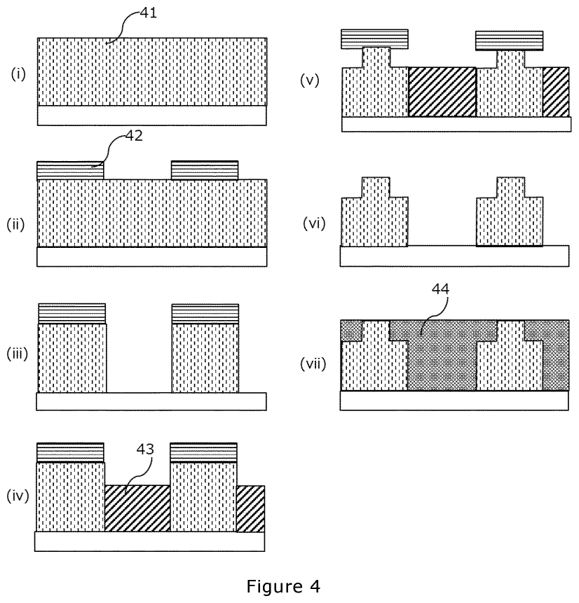

FIG. 4 is a schematic illustration showing one example of a method for forming a conductive member having a wide structure in the lateral direction at the upper part. FIG. 4(i) shows a substrate having an insulating Si-containing layer, FIG. 4(ii) shows a state in which a resist pattern 42 is formed thereon, and FIG. 4(iii) shows a state in which the insulating Si-containing layer is processed using a resist pattern. Preferable examples of the insulating Si-containing layer shown in FIG. 4(i) include a SiO₂ layer. FIG. 4(iv) shows a state in which the sacrificial layer 43 from which the upper part is removed is formed by the method according to the present invention. FIG. 4(v) shows a state in which the upper part of the insulating Si-containing layer is processed using the sacrificial layer from which the upper part is removed as a mask, and a state in which the sacrificial layer is removed thereafter is shown by FIG. 4(vi). FIG. 4(vii) shows a state in which a conductive member 44 is filled in the portion where the sacrificial layer is removed.

When the sacrificial solution contains an acid generator, patterning can be made by exposure/development to use it like a so-called resist. It is one embodiment of the present invention to perform the exposure/development, for example, after the step (4) or after the step (5).

The present invention provides a method for manufacturing a device comprising a method for manufacturing a substrate from which the upper part of the sacrificial layer is removed or a method for manufacturing a processed substrate. As needed, the substrate can be further processed, cut into chips, connected to a lead frame, and packaged with resin or the like. Preferably, the wiring is formed on the substrate by a known method. In the present invention, this packaged one is referred to as a device. Examples of the device include a semiconductor device, a liquid crystal display device, an organic EL display device, a plasma display device and a solar cell device. The device is preferably a semiconductor device.

### EXAMPLES

The present invention is described below with reference to various examples. The embodiments of the present invention are not limited to these examples.

### [Preparation of Sacrificial Solution 1]

Polymer A1 (34.8 mass %) and surfactant (0.2 mass %) are added to a mixed solvent of PGME (45.5 mass %) and PGMEA (19.5 mass %). The value of each mass % is the content rate based on the total mass of the sacrificial solution. The resulting solution is stirred at room temperature for 60 minutes. It is visually confirmed that the solutes are completely dissolved. This solution is filtered through a 0.2 μm fluororesin filter to obtain the sacrificial solution 1.

### [Preparation of Sacrificial Solutions 2 to 6]

The sacrificial solutions 2 to 6 are prepared in the same manner as the sacrificial solution 1 except that the compositions are changed to those shown in Table 1. The numerical values in Table 1 are the contents of each component (mass %) based on the total mass of the sacrificial solution.

TABLE 1

| | Polymer (A) | Solvent (B) | | Acid generator (C) | Additive (D) | |
|---|---|---|---|---|---|---|
| Sacrificial | Polymer A1 34.8 | PGME 45.5 | PGMEA 19.5 | — | Surfactant 0.2 | — |
| solution 1 | | | | | | |
| Sacrificial | Polymer A1 34.7 | PGME 45.5 | PGMEA 19.5 | — | Surfactant 0.2 | Basic |
| solution 2 | | | | | | compound 0.1 |
| Sacrificial | Polymer A1 32.8 | PGME 45.5 | PGMEA 19.5 | — | Surfactant 0.2 | Contrast |
| solution 3 | | | | | | enhancer 2.0 |
| Sacrificial | Polymer A1 32.8 | PGME 45.5 | PGMEA 19.5 | — | Surfactant 0.2 | Placticizer 2.0 |
| solution 4 | | | | | | |
| Sacrificial | Polymer A1 33.8 | PGME 45.5 | PGMEA 19.5 | Photoacid | Surfactant 0.2 | — |
| solution 5 | | | | generator 1.0 | | |
| Sacrificial | Polymer A2 34.8 | PGME 45.5 | PGMEA 19.5 | — | Surfactant 0.2 | — |
| solution 6 | | | | | | |

In the table,
Polymer A1: p-hydroxystyrene/styrene/t-butyl acrylate copolymer (polymerization ratio, respectively: 60%: 20%: 20%, Mw: 12,000)

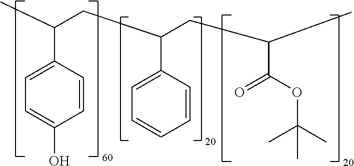

Polymer A2: m-cresol/p-cresol copolymer
   (polymerization ratio: 60:40, Mw: 12,000)

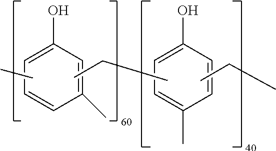

Photoacid generator: triphenylsulfonium perfluoro-1-butanesulfonate (Sigma-Aldrich)

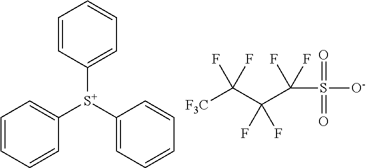 [SMILES: c1ccc([S+](c2ccccc2)c2ccccc2)cc1 ; O=S(=O)([O-])C(F)(F)C(F)(F)C(F)(F)C(F)(F)F]

Surfactant: Megafac R-41 (DIC)
Basic compound: tris[2-(2-methoxyethoxy)ethyl]amine (Tokyo Chemical Industry, hereinafter TCI)

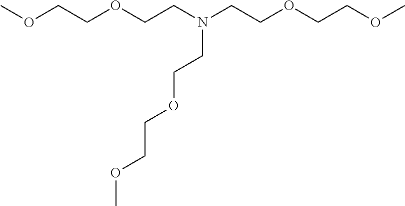

Contrast enhancer: 1,1,1-tris(4-hydroxyphenyl)ethane (TCI)

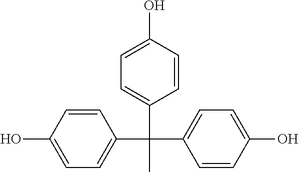 [SMILES: CC(c1ccc(O)cc1)(c1ccc(O)cc1)c1ccc(O)cc1]

Plasticizer: polyvinyl methyl ether (Mw: 57,000)

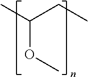

### Example 1

The sacrificial solution 1 is spin-coated on a stepped Si substrate at 1,000 rpm using a coater developer (CLEAN TRACK Mark 8, Tokyo Electron). The stepped Si substrate used has a line space: 1:1, a trench width: 10 μm, a wall width: 10 μm, a depth: 10 μm, and an aspect ratio: 1:1. This substrate is heated at 120° C. for 90 seconds under atmospheric conditions to form a sacrificial layer.

Here, a section of the obtained sacrificial layer is prepared, a photograph by SEM (SU8230, Hitachi High-Tech Fielding) is obtained, and it is observed that the sacrificial layer is embedded in the stepped substrate. The obtained results are as shown in Table 2. Good filling properties means that it is embedded without voids or the like in the vicinity of the pattern. Further, the film thickness of the sacrificial layer is measured starting from the bottom of the trench of the stepped substrate. The obtained film thickness (initial film thickness) is as shown in Table 2.

A sacrificial layer is formed in the same way as the above. On the surface of the formed sacrificial layer, an acidic aqueous solution of 8 mass % of trifluoromethylsulfonic acid (TfOH) aqueous solution is poured and retained (paddle). The contact time (paddle time) of this acid is as shown in Table 2. Thereafter, deionized water is poured onto the sacrificial layer, rinsing is performed for 20 seconds, and the acid is replaced with deionized water. The substrate is subjected to spin drying at 1,000 rpm for 2 seconds. The substrate is then heated at 130° C. for 300 seconds under atmospheric conditions. Thereafter, a 2.38 mass % TMAH aqueous solution, which is a remover, is subjected to paddling to the sacrificial layer during the remover application time shown in Table 2. Immediately thereafter, deionized water is poured onto this sacrificial layer, rinsing is performed for 20 seconds, and the TMAH aqueous solution is replaced with deionized water. The substrate is subjected to spin drying at 1,000 rpm for 2 seconds. Consequently, a sacrificial layer from which the upper part is removed (first time) is obtained.

Here, a section is prepared in the same manner as in the above-mentioned preparation of the section, and the film thickness is measured in the same manner as in the above-mentioned measurement of the film thickness. Since the initial film thickness is 12 μm in Example 1 and the film thickness after the removal treatment is 5 μm, it can be confirmed that the first film loss (removal amount of the upper part) is 7 μm.

In the same way as the above, a sacrificial layer from which the upper part is removed (first time) is formed. A 2.38 mass % TMAH aqueous solution, which is a remover, is subjected to paddling to the sacrificial layer during the remover application time shown in Table 2. Thereafter, deionized water is poured onto this sacrificial layer, rinsing is performed for 20 seconds, and the TMAH aqueous solution is replaced with deionized water. The substrate is subjected to spin drying at 1,000 rpm for 2 seconds. Consequently, a sacrificial layer from which the upper part is removed (second time) is obtained.

Here, a section is prepared in the same manner as in the above-mentioned preparation of the section, and the film thickness is measured in the same manner as in the above-mentioned measurement of the film thickness. In Example 1, the amount of film loss at the second time ((the film thickness of the sacrificial layer from which the upper part is removed (first time))-(the film thickness of the sacrificial layer from which the upper part is removed (second time))) is 0.

### Examples 2 to 7 and Comparative Examples 1 and 2

Removal of the upper part of the sacrificial layer is performed in the same manner as in Example 1 except that conditions of the sacrificial solution, the acidic aqueous solution, the acid contact time and the remover application time shown in Table 2 are applied. In the same manner as in Example 1, the filling properties, the film thickness and the amount of film loss are also measured, and the obtained results are as shown in Table 2.

In Comparative Example 1, contact with the acidic aqueous solution is not performed.

TABLE 2

| | | | | | | | Acid | Remover | | |
|---|---|---|---|---|---|---|---|---|---|---|
| | | | | Film | | | contact | application | Film loss | |
| | | Sacrificail | Filling | thickness | Acidic | | time | time | amount (μm) | |
| | | solution | properties | (μm) | aqueous solution | | (second) | (second) | first | second |
| Example | 1 | Sacrificial | good | 12 | 8 | mass % TfOH | 60 | 90 | 7 | 0 |
| | | solution 1 | | | | | | | | |
| | 2 | Sacrificial | good | 12 | 8 | mass % TfOH | 60 | 90 | 7 | 0 |
| | | solution 2 | | | | | | | | |
| | 3 | Sacrificial | good | 12 | 8 | mass % TfOH | 60 | 90 | 7 | 0 |
| | | solution 3 | | | | | | | | |
| | 4 | Sacrificial | good | 12 | 8 | mass % TfOH | 60 | 90 | 7 | 0 |
| | | solution 4 | | | | | | | | |
| | 5 | Sacrificial | good | 12 | 1 | mass % TfOH | 120 | 90 | 7 | 0 |
| | | solution 1 | | | | | | | | |
| | 6 | Sacrificial | good | 12 | 0.1 | mass % TfOH | 300 | 90 | 7 | 0 |
| | | solution 1 | | | | | | | | |
| | 7 | Sacrificial | good | 12 | 0.01 | mass % TfOH | 600 | 90 | 7 | 0 |
| | | solution 1 | | | | | | | | |
| Comparative | 1 | Sacrificial | good | 12 | — | | — | 600 | 0 | 0 |
| Example | | solution 5 | | | | | | | | |
| | 2 | Sacrificial | good | 12 | 8 | mass % TfOH | 60 | 600 | 3 | 3 |
| | | solution 6 | | | | | | | | |

In the table,
TfOH: trifluoromethanesulfonic acid (Sigma-Aldrich)

In Examples 1 to 7 and Comparative Example 1, it is confirmed that no further film loss is occurred after the second application of the remover. For example, in Example 1, even if the second remover is applied, the film thickness is 5 μm, and it is confirmed that the film is not reduced from the first removal. In Comparative Example 2, it is confirmed that the film is reduced not only by the first application of the remover but also by the second application of the remover.

### EXPLANATION OF SYMBOLS

1. substrate
2. wall
3. trench
4. trench bottom
5. wall width
6. trench width
7. trench depth
8. sacrificial layer
9. initial film thickness
10. acid aqueous solution
11. remover
12. film thickness of after removal
13. amount of film loss
14. substrate
15. sacrificial layer from which the upper part is removed
16. surface treatment
17. processed substrate
31. conductive Si-containing layer
32. insulating Si-containing layer
33. sacrificial layer from which the upper part is removed
41. insulating Si-containing layer
42. resist pattern
43. sacrificial layer from which the upper part is removed
44. conductive member

1-15. (canceled)

16. A method for removing the upper part of a sacrificial layer comprising the following steps:
(1) applying a sacrificial solution comprising a polymer having an acid-dissociable protective group (A) and a solvent (B) above a substrate (preferably a pattern substrate);
(2) forming a sacrificial layer (preferably by heating) from the applied sacrificial solution;
(3) subjecting an acidic aqueous solution to contact with the surface of the sacrificial layer (preferably the contact is carried out by a paddle method or dip method, and/or preferably heated after contact); and
(4) applying a remover to the sacrificial layer.

17. The method according to claim 16, further comprising a step in which chemical mechanical polishing of the sacrificial layer is carried out between (2) and (3).

18. The method according to claim 16, wherein the acid-dissociable protective group of the polymer (A) is a group represented by at least one formula selected from the group consisting of —C(R¹)(R²)(R³), —C(R¹)(R²)(OR⁴) and —C(R⁵)(R⁶)(OR⁴),
where
R¹ to R⁴ are each independently alkyl, cycloalkyl, aryl, aralkyl or alkenyl, R¹ and R² can be combined together to form a ring, and
R⁵ and R⁶ are each independently hydrogen, alkyl, cycloalkyl, aryl, aralkyl or alkenyl: preferably, the main chain and/or side chain of the polymer (A) has the acid-dissociable protective group.

19. The method according to claim 16, wherein the polymer (A) comprises a repeating unit represented by the formulae (P-1), (P-2) and/or (Q): 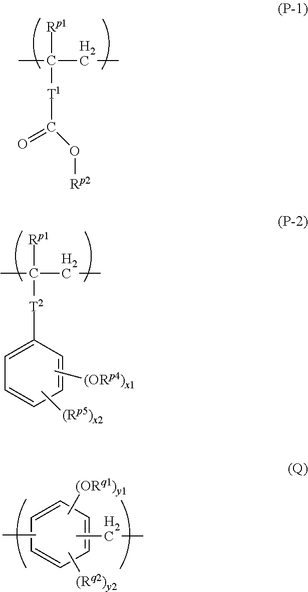
where
R^{p1} and R^{p3} are each independently hydrogen or C₁₋₄ alkyl,
R^{p2}, R^{p4} and R^{q1} are each independently linear, branched or cyclic C₃₋₁₅ alkyl (where the alkyl can be substituted with fluorine and —CH₂— in the alkyl can be replaced with —O—);
x1 and y1 are each independently 1 to 3;
T¹ and T² are each independently a single bond or a C₁₋₁₂ linking group, and
R^{p5} is each independently C₁₋₅ alkyl (where —CH₂— in the alkyl can be replaced with —O—);
R^{q2} is each independently hydroxy or C₁₋₅ alkyl (where —CH₂— in the alkyl can be replaced with —O—); and
x2 and y2 are each independently 0 to 2.

20. The method according to claim 16, wherein the polymer (A) comprises a repeating unit represented by the formulae (P-1) and/or (P-2), and optionally one represented by the formulae (P-3) and/or (P-4): 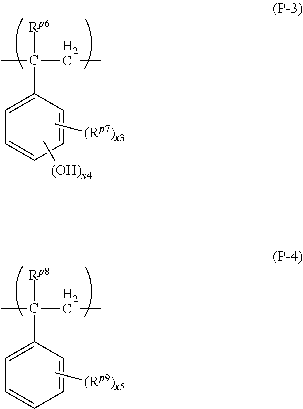
where
R^{p6} and R^{p8} are each independently hydrogen or C₁₋₃ alkyl, and
R^{p7} and R^{p9} are each independently C₁₋₅ alkyl (where —CH₂— in the alkyl can be replaced with —O—);
x3 and x5 are each independently 0 to 2; and
x4 is 1 to 2.

21. The method according to claim 16, wherein the content of the polymer (A) is 5 to 50 mass % based on the total mass of the sacrificial solution:
preferably, the content of the solvent (B) is 50 to 95 mass % based on the total mass of the sacrificial solution.

22. The method according to claim 16, wherein the sacrificial solution comprises an acid generator (C), and the content of the acid generator (C) is 0 to 5 mass % based on the total mass of the sacrificial solution:
preferably, the content of the acid generator (C) is 0 mass % based on the total mass of the sacrificial solution.

23. The method according to claim 16, wherein the sacrificial solution further comprises an additive (D), where the additive (D) is a surfactant, a basic compound, a contrast enhancer, a plasticizer, or a mixture of any of these.

24. The method according to claim 16, wherein the sacrificial solution comprises the followings, based on the total mass of the sacrificial solution:
0 to 2 mass % of a surfactant;
0 to 1 mass % of a basic compound;
0 to 5 mass % of a contrast enhancer; and/or
0 to 5 mass % of a plasticizer.

25. A sacrificial solution comprising a polymer having an acid-dissociable protective group (A) and a solvent (B), wherein the sacrificial solution forms a sacrificial layer, the sacrificial layer comes into contact with an acidic aqueous solution, and the upper part of the sacrificial layer is removed by a remover.

26. An acidic aqueous solution for being subjected to contact with a sacrificial layer, comprising an acid selected from the group consisting of the compounds represented by the following formulae (ZA), (ZB) and (ZC), and water:
Rz O₃H (ZA)
where
R^{ZA} is C₁₋₁₀ fluorine-substituted alkyl, C₁₋₁₀ fluorine-substituted alkyl ether, C₆₋₂₀ fluorine-substituted aryl, C₁₋₁₀ fluorine-substituted acyl or C₆₋₂₀ fluorine-substituted alkoxyaryl; 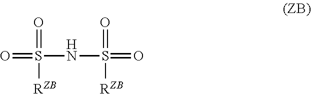
where
R^{ZB} is each independently C₁₋₁₀ fluorine-substituted alkyl, C₁₋₁₀ fluorine-substituted alkyl ether, C₆₋₂₀ fluorine-substituted aryl, C₁₋₁₀ fluorine-substituted acyl or C₆₋₂₀ fluorine-substituted alkoxyaryl, and the two R^{ZB} can be combined together to form a fluorine-substituted heterocyclic structure; and 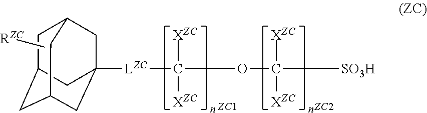
where
R^{ZC} is hydrogen, C₁₋₆ alkyl, C₁₋₆ alkoxy or hydroxy, and L^{ZC} is oxy or carbonyloxy;
X^{ZC} is each independently hydrogen or fluorine;
n^{ZC1} is 0 to 10; and
n^{ZC2} is 0 to 21.

27. A method for manufacturing a processed substrate comprising the following steps:
preparing a substrate from which the upper part of the sacrificial layer is removed by the method according to claim 16;
(5) performing surface treatment on the portion of the substrate from which the sacrificial layer is removed;
(6) removing the residual sacrificial layer; and
(7) subjecting the substrate to further processing.

28. A method for manufacturing a processed substrate comprising the following steps: preparing a substrate from which the upper part of the sacrificial layer is removed by the method according to claim 16;
(5)′ processing the substrate by isotropic etching; and
(6)′ removing all or part of the residual sacrificial layer:
where
the steps (5)′ and (6)′ are carried out only once in this order or repeated alternately.

29. The method for manufacturing a processed substrate according to claim 28, further comprising the following step:
(7)′ filling the portion where the sacrificial layer is removed with a conductive member.

30. A method for manufacturing a device, comprising the method according to claim 16:
preferably, the method further comprises a step of forming a wiring on the substrate; or
preferably, the device is a semiconductor device.
